(19) United States
(12) Patent Application Publication
(10) Pub. No.: US 2024/0258470 A1
(43) Pub. Date: Aug. 1, 2024

(54) HIGH REFRACTIVE INDEX STRUCTURED COATING FOR EFFICIENT LIGHT EXTRACTION FROM LEDS AND PCLEDS

(71) Applicant: Lumileds LLC, San Jose, CA (US)

(72) Inventors: Daniel B. ROITMAN, Menlo Park, CA (US); Franklin CHIANG, San Jose, CA (US); Vernon WONG, Mountain View, CA (US)

(73) Assignee: Lumileds LLC, San Jose, CA (US)

(21) Appl. No.: 18/630,689

(22) Filed: Apr. 9, 2024

Related U.S. Application Data
(63) Continuation of application No. PCT/US22/46411, filed on Oct. 12, 2022.
(60) Provisional application No. 63/257,399, filed on Oct. 19, 2021.

(51) Int. Cl. H01L 33/50

(52) U.S. Cl. CPC H01L 33/505; H01L 33/502; H01L 33/507

(57) ABSTRACT

This specification discloses LEDs, pcLEDs, and arrays of LEDs or pcLEDs in which the LEDs or pcLEDs comprise a structured high refractive index coating on a light output surface that improves light extraction from the device through the light output surface. The coating is formed additively instead of by a subtractive process that removes material from the surface, and consequently can avoid the disadvantages associated with subtractive processes.

### CROSS REFERENCE TO RELATED APPLICATIONS

This application is a continuation of PCT Application PCT/US2022/046411 filed Oct. 12, 2022, which claims benefit of priority to U.S. Provisional Patent Application No. 63/257,399 filed Oct. 19, 2021, which is incorporated herein by reference in its entirety.

### FIELD OF THE INVENTION

The invention relates generally to semiconductor LEDs and pcLEDs, LED and pcLED arrays, light sources comprising LED and pcLED arrays, and displays comprising LED and pcLED arrays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

LEDs and pcLEDs have been widely used to create different types of displays, matrices and light engines including automotive adaptive headlights, augmented-reality (AR) displays, virtual-reality (VR) displays, mixed-reality (MR) displays, smart glasses and displays for mobile phones, smart watches, monitors and TVs, and flash illumination for cameras in mobile phones. The individual LED pixels in these architectures can have an area of a few square millimeters down to a few square micrometers depending on the matrix or display size and its pixel per inch requirements. LED matrices/displays may for example be realized by transfer and attachment of individual pixels from a donor substrate to a controller backplane or electronic board or be created by a monolithic approach where a monolithically integrated array of LED pixels is processed into an LED module on a donor epitaxial wafer and then transferred and attached to a controller backplane.

There is a need to improve light extraction and control of light output distribution in LEDs and pcLEDs. This applies for example to pcLEDs in which the wavelength converting structure is a ceramic phosphor platelet. Such platelets are typically smooth rectangular slabs made from a high refractive index ceramic (for example, RI˜1.47). The air-ceramic interface through which light is output by the device exhibits a large RI discontinuity resulting in a significant fraction of the light being waveguided, absorbed, and converted to heat inside the platelet instead of being output from the device. This similarly applies to direct emitting LEDs (not comprising a wavelength converter) for which the light output surface is formed from a high refractive index material, for example in which the light output surface is formed from sapphire (RI˜1.77), SiC (RI˜2.65), GaN (RI˜2.38), or GaP (RI˜3.31).

Light extraction into air through a high refractive index surface may be enhanced by roughening the surface by etching, with abrasives, or by other subtractive techniques that remove material from the surface to roughen it. Such roughening processes can be expensive, difficult to control or tune, undesirably affect the light emission pattern and efficiency, create mechanical defects or cause mechanical stability issues (e.g., localized thin regions, crack initiation points), and cause contamination.

### SUMMARY

This specification discloses wavelength converting structures, LEDs, pcLEDs, and arrays of LEDs or pcLEDs in which the wavelength converting structures, LEDs, or pcLEDs comprise a structured high refractive index coating on a light output surface that improves light extraction from through the light output surface. The coating is formed additively instead of by a subtractive process that removes material from the surface, and consequently can avoid the disadvantages associated with subtractive processes referred to above. The structured high refractive index coating comprises particles dispersed in a high refractive index binder. The binder and the particles are transparent to (do not absorb) light at wavelengths emitted by the device through the light output surface.

Individual wavelength converting structures, pcLEDs, and directing emitting LEDs disclosed herein may have light output surfaces having areas ranging from a few square micrometers (microLEDs) to square millimeters (conventional LEDs). Arrays disclosed herein may comprise any suitable number of such pcLEDs or direct emitting LEDs arranged in any suitable manner. The wavelength converting structures, pcLEDs, direct emitting LEDs, and arrays disclosed herein may be advantageously employed in various of the devices and applications listed above in the Background section.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system comprising an adaptive illumination system.

FIG. 6 schematically illustrates an example display (e.g., AR/VR/MR) system that includes an adaptive illumination system.

FIG. 7 shows a schematic cross-sectional view of an example wavelength converting structure comprising a structured high refractive index coating disposed on a light output surface.

FIG. 8 shows a schematic cross-sectional view of an example pcLED comprising a structured high refractive index coating disposed on a light output surface of a wavelength converting structure.

FIG. 9 shows a schematic cross-sectional view of an example direct emitting (not phosphor converted) LED comprising a structured high refractive index coating disposed on a light output surface.

FIG. 10 shows a schematic cross-sectional view of another example wavelength converting structure comprising a structured high refractive index coating disposed on a light output surface.

FIG. 11 shows a schematic cross-sectional view of another example pcLED comprising a structured high refractive index coating disposed on a light output surface of a wavelength converting structure.

FIG. 12 shows a schematic cross-sectional view of another example direct emitting (not phosphor converted) LED comprising a structured high refractive index coating disposed on a light output surface.

FIG. 13 shows a flow chart for a method for providing a high refractive index structured coating on an LED or pcLED.

FIG. 14 shows a flow chart for another method for providing a high refractive index structured coating on an LED or pcLED.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED.

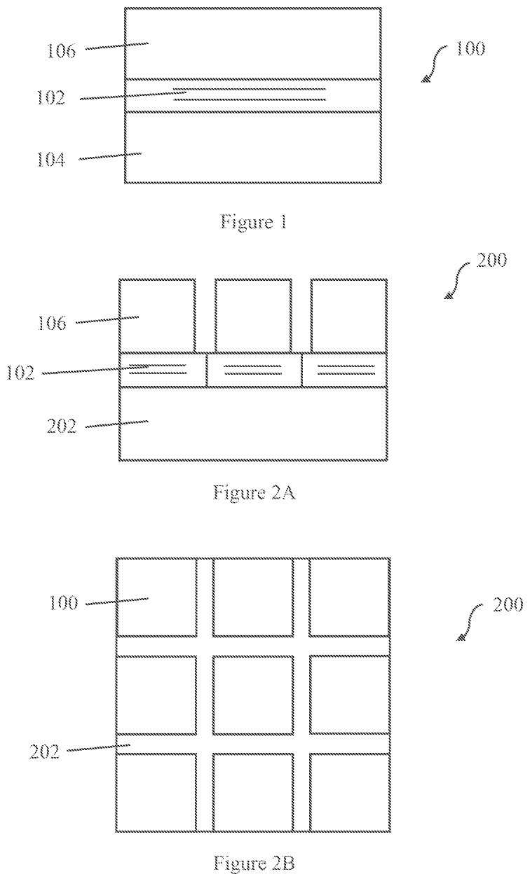

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED and may be formed from any suitable materials.

Although FIGS. 2A-2B, show a three-by-three array of nine pcLEDs, such arrays may include for example tens, hundreds, or thousands of LEDs. Individual LEDs (pixels) may have widths (e.g., side lengths) in the plane of the array, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular pixels arranged in a symmetric matrix, the pixels and the array may have any suitable shape or arrangement.

LEDs having dimensions in the plane of the array (e.g., side lengths) of less than or equal to about 50 microns are typically referred to as microLEDs, and an array of such microLEDs may be referred to as a microLED array.

An array of LEDs, or portions of such an array, may be formed as a segmented monolithic structure in which individual LED pixels are electrically isolated from each other by trenches and/or insulating material, but the electrically isolated segments remain physically connected to each other by portions of the semiconductor structure.

The individual LEDs in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels. Depending on the application, emitted light may be spectrally distinct, adaptive over time, and/or environmentally responsive. Such light emitting pixel arrays may provide pre-programmed light distribution in various intensity, spatial, or temporal patterns. The emitted light may be based at least in part on received sensor data and may be used for optical wireless communications. Associated electronics and optics may be distinct at a pixel, pixel block, or device level.

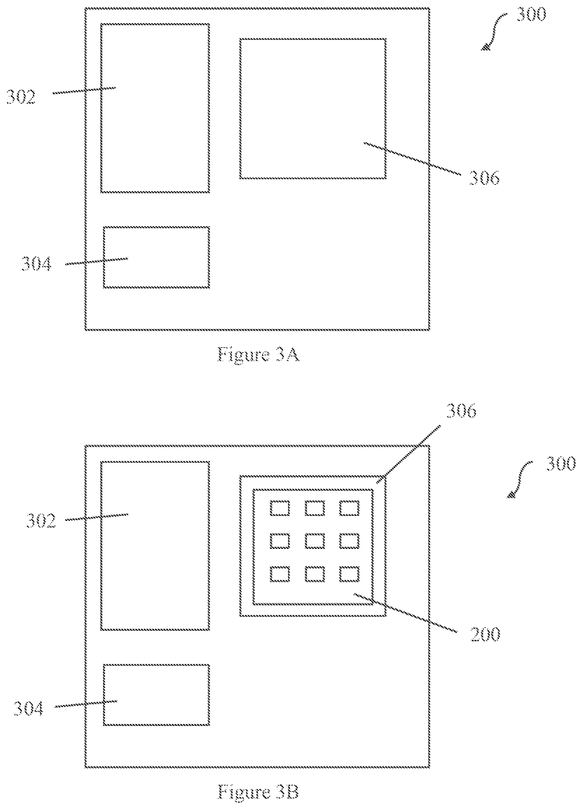

As shown in FIGS. 3A-3B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

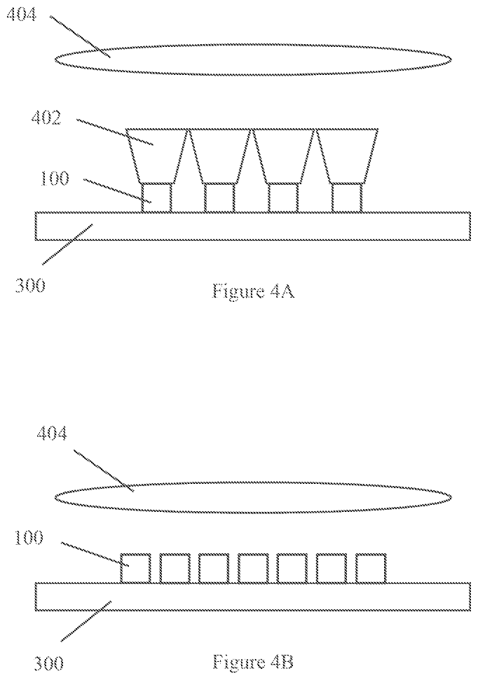

Individual pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B a pcLED array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when pcLEDs can be spaced sufficiently close to each other and may also be used in automobile headlights as well as in camera flash applications. A microLED display application may use similar optical arrangements to those depicted in FIGS. 4A-4B, for example. Generally, any suitable arrangement of optical elements may be used in combination with the LED arrays described herein, depending on the desired application.

An array of independently operable LEDs may be used in combination with a lens, lens system, or other optical system (e.g., as described above) to provide illumination that is adaptable for a particular purpose. For example, in operation such an adaptive lighting system may provide illumination that varies by color and/or intensity across an illuminated scene or object and/or is aimed in a desired direction. A controller can be configured to receive data indicating locations and color characteristics of objects or persons in a scene and based on that information control LEDs in an LED array to provide illumination adapted to the scene. Such data can be provided for example by an image sensor, or optical (e.g., laser scanning) or non-optical (e.g., millimeter radar) sensors. Such adaptive illumination is increasingly important for automotive, mobile device camera, VR, and AR applications.

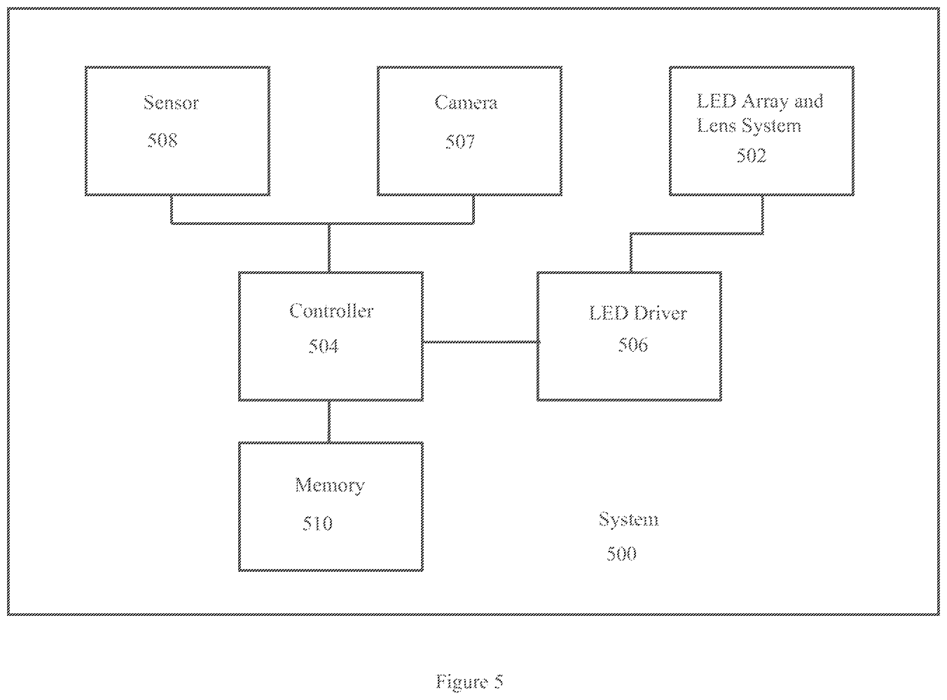

FIG. 5 schematically illustrates an example camera flash system 500 comprising an LED array and lens system 502, which may be similar or identical to the systems described above. Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and adaptive illumination system 502 may be controlled by controller 504 to match their fields of view.

Sensors 508 may include, for example, positional sensors (e.g., a gyroscope and/or accelerometer) and/or other sensors that may be used to determine the position, speed, and orientation of system 500. The signals from the sensors 508 may be supplied to the controller 504 to be used to determine the appropriate course of action of the controller 504 (e.g., which LEDs are currently illuminating a target and which LEDs will be illuminating the target a predetermined amount of time later).

In operation, illumination from some or all pixels of the LED array in 502 may be adjusted—deactivated, operated at full intensity, or operated at an intermediate intensity. Beam focus or steering of light emitted by the LED array in 502 can be performed electronically by activating one or more subsets of the pixels, to permit dynamic adjustment of the beam shape without moving optics or changing the focus of the lens in the lighting apparatus.

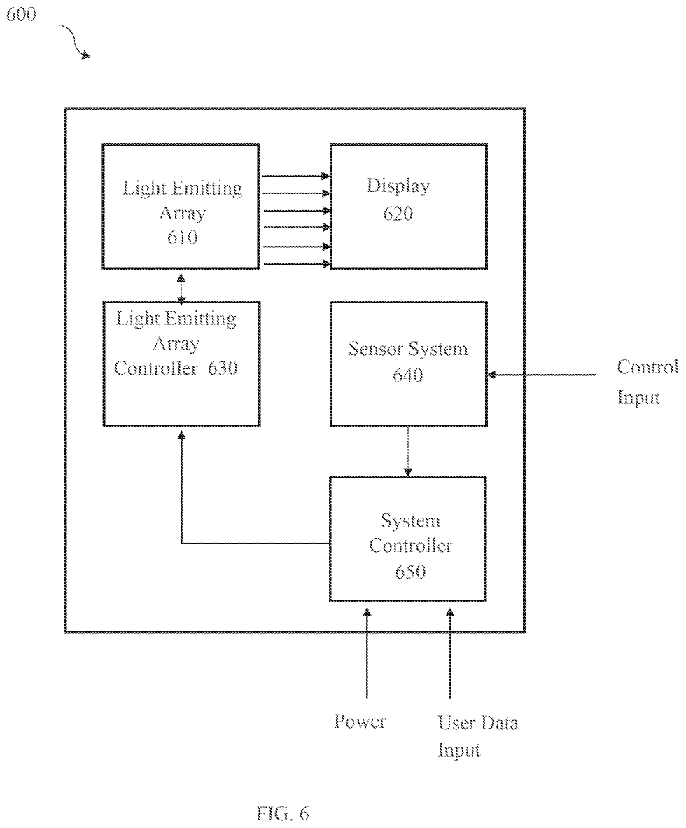

FIG. 6 schematically illustrates an example display (e.g., AR/VR/MR) system 600 that includes an adaptive light emitting array 610, display 620, a light emitting array controller 630, sensor system 640, and system controller 650. Control input is provided to the sensor system 640, while power and user data input is provided to the system controller 650. In some embodiments modules included in system 600 can be compactly arranged in a single structure, or one or more elements can be separately mounted and connected via wireless or wired communication. For example, the light emitting array 610, display 620, and sensor system 640 can be mounted on a headset or glasses, with the light emitting controller and/or system controller 650 separately mounted.

The light emitting array 610 may include one or more adaptive light emitting arrays, as described above, for example, that can be used to project light in graphical or object patterns that can support AR/VR/MR systems. In some embodiments, arrays of microLEDs can be used.

System 600 can incorporate a wide range of optics in adaptive light emitting array 610 and/or display 620, for example to couple light emitted by adaptive light emitting array 610 into display 620.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As summarized above, this specification discloses wavelength converting structures, pcLEDs, and arrays of LEDs or pcLEDs in which the wavelength converting structures, LEDs, or pcLEDs comprise a structured high refractive index coating on a light output surface that improves light extraction through the light output surface. The structured high refractive index coating comprises particles dispersed in a high refractive index binder. The binder and the particles are transparent to (do not absorb) light at wavelengths emitted by the device through the light output surface.

The binder may have a refractive index higher than, lower than, index matched to, or approximately index matched to the refractive index of the material forming the light output surface on which the coating is disposed. The binder and the material forming the light output surface are approximately index matched if the relative mismatch between the binder and the material forming the light output surface (|difference in refractive indices/refractive index of the binder) is less than or equal to about 0.10 or less than or equal to about 0.05. The binder may have a refractive index of about 1.4 to about 1.57, or about 1.4 to about 1.65, or about 1.4 to about 1.70, for example, for light having a wavelength of 589 nm. The binder may have an index of refraction greater than or equal to 1.65 at 589 nm, for example. The binder may have an index of refraction of about 1.65 to about 1.70 at 589 nm, for example. The binder may be or comprise a high refractive index siloxane, for example. The binder may be or comprise a zirconia-silicone nanocomposite material or a titania-silicone nanocomposite material, for example.

As further discussed below, the structured high refractive index coating may comprise cavities (e.g., pores) located in spaces between adjacent particles. Internal surfaces of the cavities may be defined, for example, by surfaces of the particles and/or surfaces of portions of the binder. The cavities in the structured high refractive index coating may comprise, for example, vacuum, air, or another gas and typically have a refractive index of about one. Consequently, the interfaces between the cavities and the surrounding material (e.g., particles and/or binder) in the structured high refractive index coating are strongly light scattering.

The particles dispersed in the binder may be index matched or approximately index matched to the refractive index of the binder. The binder and the particles are approximately index matched if the relative mismatch between the binder and the particles (|difference in refractive indices|/refractive index of the binder) is less than or equal to about 0.10 or less than or equal to about 0.05. For example, the binder may have a refractive index of about 1.65 and the particles have a refractive index of 1.65±0.1 (an ˜0.06 relative mismatch). If the particles are index matched or approximately index matched to the binder, light will not be strongly scattered at the binder-particle interfaces.

The particles dispersed in the binder may be solid (not hollow). Alternatively, the particles dispersed in the binder may be hollow, for example comprising an outer shell of high refractive index material surrounding or partially surrounding one or more interior cavities. The cavities in the hollow particles may comprise, for example, vacuum, air, or another gas, and typically have a refractive index of about one. Consequently, the interface between the outer shell of the particle and the hollow interior is strongly light scattering.

In some variations (pcLEDs), the light output surface on which the high refractive index structured coating is disposed is an outer surface of a wavelength converting structure such as, for example, a high index of refraction ceramic phosphor platelet. In other variations (direct emitting LEDs), the light output surface on which the high refractive index structured coating is disposed is an outer surface of a high refractive index layer that is transparent to light emitted by the active region of the LED. For example, the light output surface may be a surface of a layer of sapphire, SiC, GaN, or GaP.

Light coupling between the binder in the structured high refractive index coating and the high index of refraction light output surface may be nearly 100% if their refractive indices are matched or approximately matched. Even without index matching or approximate matching, the efficiency with which light couples into the structured high refractive index coating through the light output surface will be greater than the efficiency with which light would couple through the light output surface into air. If the binder has a refractive index greater than or equal to that of the light output surface, total internal reflection of light emitted by the LED's active region or wavelength converting structure and incident on the interface between the light output surface and the structured high refractive index coating will not occur.

In some variations an outer surface of the structured high index of refraction coating is roughened by the presence of the particles. This roughened surface of the coating breaks the waveguiding and enables light to readily exit the coating, thus improving light extraction from the device. The roughened surface may have a roughness Ra of, for example, about 0.15 microns to about 5 microns, about 0.15 microns to about 3 microns, or about 0.15 microns to about 1 micron, preferably between about 0.5× to about 5× the peak emission wavelength of the LED or pcLED.

In some variations the output surface of the coating is not roughened by the presence of the particles, but the particles are hollow and consequently strongly light scattering. This light scattering improves light extraction from the coating.

In some variations the outer surface of the structured high index of refraction coating is roughened by the presence of the particles and the particles are hollow and strongly scattering. Light extraction from the device is improved by the roughened surface and the light scattering.

In some variations the outer surface of the structured high index of refraction coating is roughened by the particles, and the structured high index of refraction coating comprises strongly light scattering cavities located in spaces between adjacent particles as described above. Light extraction from the device is improved by the roughened surface and the light scattering.

Solid (not hollow) particles in a structured high index of refraction coating as disclosed herein may be formed from materials such as for example titania, Niobium pentoxide, or zirconia, have indices of refraction of for example about 2.16 to about 2.61, and have diameters of for example about 0.15 microns to about 5 microns, preferably between about 0.5× to about 5× the peak emission wavelength of the LED or pcLED. The particle size distribution may for example be monodisperse, with about 25% of the particles having sizes within +10% of the median diameter. Alternatively, the particle size distribution may be multimodal, for example a bimodal distribution or a Dinger-Funk distribution (giving maximum packing density). The solid particles may for example have spherical shapes, or any other suitable shapes.

Hollow particles in a structured high index of refraction coating may be formed from materials such as for example silica, alumina, or titania, have outer shells having indices of refraction of for example about 1.45 to about 2.61, preferably about 1.45, and have diameters of for example about 150 nm to about 5 microns, preferably between about 0.5× to about 5× the peak emission wavelength of the LED or pcLED. The particle size distribution may for example be monodisperse, with about 25% of the particles having sizes within ±10% of the median diameter. Alternatively, the particle size distribution may be multimodal, for example a bimodal distribution or a Dinger-Funk distribution (giving maximum packing density). The hollow particles may for example have spherical shapes, or any other suitable shapes.

The structured high index of refraction coating may be formed additively by, for example, preparing a solution comprising the binder, the particles, and optionally a solvent and spraying or otherwise dispensing the solution onto the light output surface of the LED(s) or pcLED(s). Any suitable solvent may be used. After dispensing the solution to coat the light output surface, any solvents used may be evaporated out and the coating may optionally be cured.

A structured high index of refraction coating comprising cavities located in the open spaces between adjacent particles as described above may be prepared, for example, by depositing the particles without binder and then subsequently growing a thin binder film between the particles to bind the particles to each other and to the light output surface of the LED or pcLED. The particles may be deposited, for example, from a suspension by rapid sedimentation (by centrifugation), by electrophoretic deposition, or by dispensing a slurry and evaporating the dispersant. The binder film may be, for example, a sol-gel silica film bridging the particles or a thin (e.g., about 10 nm to about 100 nm) interparticle film grown by atomic layer deposition (ALD). The ALD film may be a silicon nitride film, for example.

In some variations, the particles in the coating self-organize during deposition to form an ordered array, which may be close-packed. The ordered array of particles may affect the angular distribution of light emitted by the LED or pcLED and transmitted through the high index structured coating similarly to a lens or array of lenses, for example by narrowing the cone angle of emission from the device compared to a device lacking the high refractive index structured coating.

The thickness of the structured high index of refraction coating measured perpendicularly to the light output surface may be, for example, less than about 250 nm.

In some variations, the coating disposed directly on the light output surface as described above is a first coating, and the high refractive index structured coating comprises one or more additional layers (e.g., a second coating, or a second coating and a third coating) disposed in a stack on the first coating. The one or more additional coatings may comprise binders and particles that have refractive indices lower than those of the coatings disposed beneath them, closer to the light output surface. This arrangement reduces the difference between the refractive index of ambient air and that of the outermost layer of the high index of refraction structured coating, further enhancing the efficiency with which light couples out of the LED or pcLED into the ambient air.

In some variations the one or more additional coating layers comprises particles as described above. In other variations the one or more additional coating layers do not comprise particles.

The one or more additional coating layers may lack particles, be optically homogenous, and each have an optical thickness perpendicular to the first coating layer of about ¼ of a wavelength of light emitted by the active layer of the LED or the wavelength converting structure of the pcLED.

In some variations, the structured high index of refraction coating comprises a first coating layer disposed on a light output surface of an LED or a pcLED, and a second coating layer disposed on the first coating layer. The first coating layer comprises particles dispersed in and index matched to, or approximately index matched to, a binder having an index of refraction of about 1.65 to about 1.70. The particles may be solid or hollow as described above. The second coating layer lacks particles, is optically homogenous, has an index of refraction about 1.40 to about 1.50, and has an optical thickness perpendicular to the first coating layer of about ¼ of a wavelength of light emitted by the active layer of an LED or about ¼ of a wavelength of light emitted by the wavelength converting structure of a pcLED.

Generally, in the examples of FIGS. 7-12 discussed below the structured high refractive index coating, its constituent binders and particles, and the light output surface (of, e.g., a wavelength converting layer or a transparent substrate) on which the structured high refractive index coating is disposed may have any of the properties and combinations of properties described above. The specific example materials and device properties discussed below in relation to these figures should not be understood as limiting.

FIG. 7 shows a schematic cross-sectional view of an example wavelength converting structure 700 comprising a structured high refractive index coating disposed on a light output surface of a layer 715 of wavelength converting material. The coating comprises particles 705 dispersed in a binder 710. Layer 715 may for example be or comprises a high refractive index ceramic phosphor material. Binder 710 may have a refractive index of, for example, about 1.65 to about 1.70. Particles 705 may have refractive indices matching or approximately matching that of the binder. Particles 705 may be solid or hollow. The structured high index of refraction coating may comprise strongly light scattering cavities located in spaces between adjacent particles, as described above.

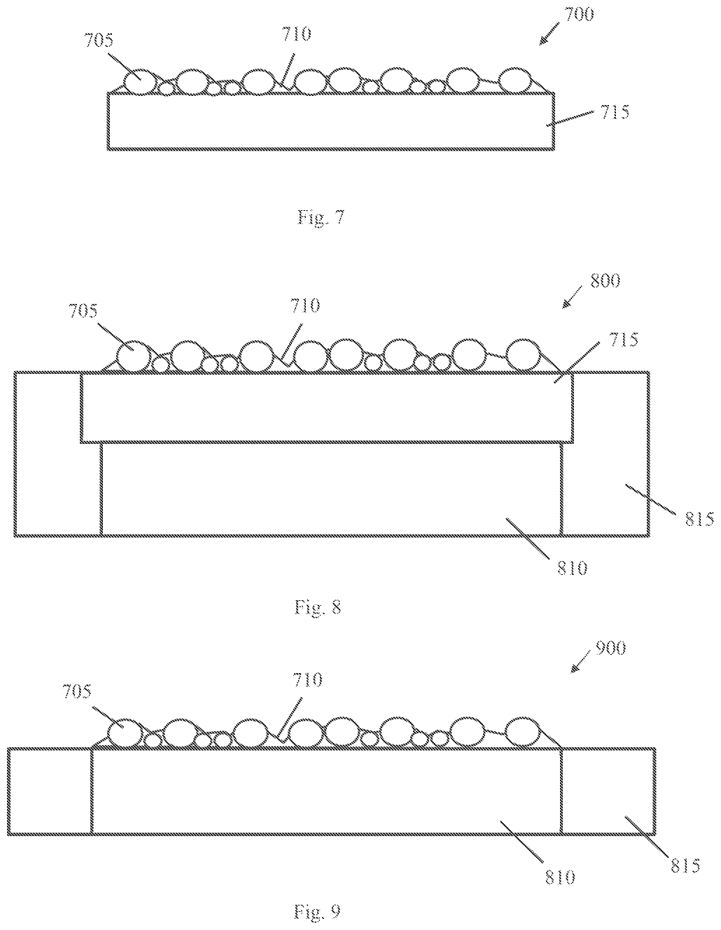

FIG. 8 shows a schematic cross-sectional view of an example pcLED 800 comprising an example wavelength converting structure as described above with respect to FIG. 7 disposed on a semiconductor LED 810. Example pcLED 800 also includes reflective side walls 815. Reflective side walls 815 may be or comprise, for example, thin reflective metal layers, distributed Bragg reflectors formed from thin stacks of dielectric or semiconductor materials, or light scattering particles dispersed in a (e.g., silicone) binder.

FIG. 9 shows a schematic cross-sectional view of an example direct emitting (not phosphor converted) LED 900 comprising a structured high refractive index coating as described above with respect to FIG. 7 disposed on a light output surface of a semiconductor LED 810. Example direct emitting LED 900 also comprises reflective side walls 815 as described above.

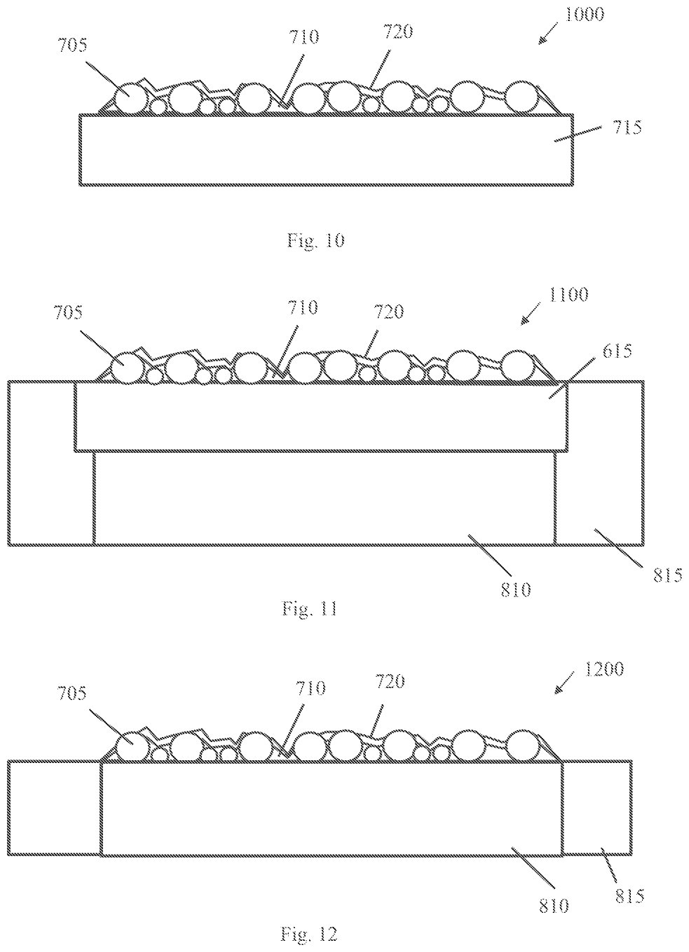

FIG. 10 shows a schematic cross-sectional view of an example wavelength converting structure 100 like that described above with respect to FIG. 7. In example wavelength converting structure 1000 the structured high index of refraction coating comprises an additional layer 720 disposed on the layer comprising particles 705 dispersed in binder 710. Additional layer 720 has a refractive index less than that of binder 710 and may optionally have an optical thickness of about ¼ wavelength for light emitted from the wavelength converting structure. Additional layer 720 may have an index of refraction of for example about 1.40 to about 1.50.

FIG. 11 shows a schematic cross-sectional view of an example pcLED 1100 like that described above with respect to FIG. 8. In example pcLED 1100 the structured high refractive index coating comprises an additional layer 720 as described above with respect to FIG. 10.

FIG. 12 shows a schematic cross-sectional view of an example direct emitting (not phosphor converted) LED 1200 like that disclosed in FIG. 9. In example direct emitting LED 1200 the structured high refractive index coating comprises an additional layer 720 as described above with respect to FIG. 10.

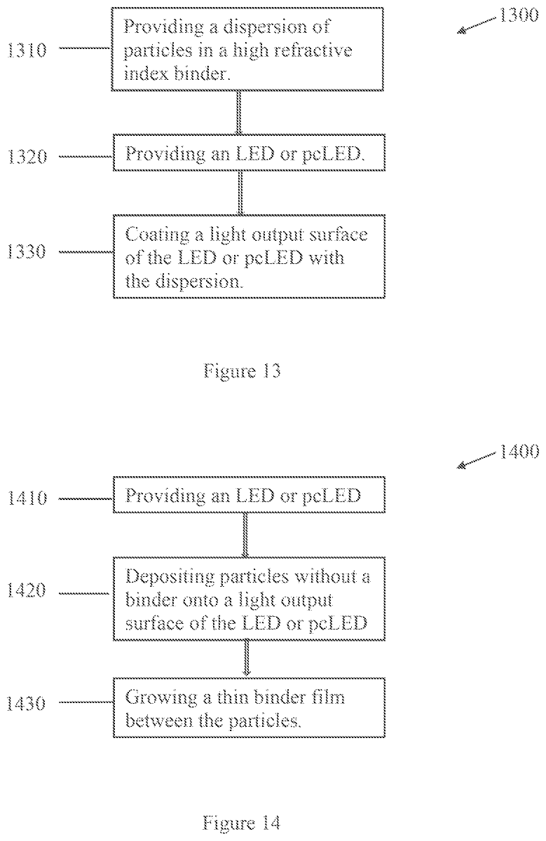

Referring now to FIG. 13 a method 1300 for providing a high refractive index structured coating on an LED or pcLED comprises: 1310 providing (e.g., preparing or obtaining) a dispersion of particles in a high refractive index binder, 1320 providing (e.g., preparing or obtaining) an LED or pcLED; and 1330 coating a light output surface of the LED or pcLED with the dispersion.

Referring now to FIG. 14, a method 1400 for providing a high refractive index structured coating on an LED or pcLED comprises: 1410 providing (e.g., preparing or obtaining) an LED or pcLED; 1420 depositing particles without a binder onto a light output surface of the LED or pcLED; and 1430 growing a thin binder film between the particles.

Although methods 13 and 14 refer to a single LED or pcLED, these methods may be performed simultaneously on LEDs or pcLEDs in an array or in an undiced wafer. Substantially identical methods may be used to provide a high refractive index structured coating on a wavelength converting structure prior to attaching the wavelength converting structure to an LED. The wavelength converting structure may, for example, be coated and then diced. The coated wavelength converting structure dice may then be attached to individual LEDs.

This disclosure is illustrative and not limiting. Further modifications will be apparent to one skilled in the art in light of this disclosure and are intended to fall within the scope of the appended claims.

What is claimed is:

1. A wavelength converting structure comprising:
a layer of wavelength converting material configured to absorb light at a first wavelength and in response emit light at a second wavelength; and
a coating disposed on a light output surface of the layer of wavelength converting material, the coating comprising at least a first layer comprising particles dispersed in a binder, the first layer disposed on the light output surface, the binder having an index of refraction at the second wavelength greater than or equal to an index of refraction at the second wavelength of the light output surface.

2. The wavelength converting structure of claim 1, wherein the layer of wavelength converting material is or comprises a ceramic phosphor platelet.

3. The wavelength converting structure of claim 1, wherein the particles are solid, transparent to light at the second wavelength, and have a refractive index at the second wavelength that matches or approximately matches the refractive index of the binder at the second wavelength.

4. The wavelength converting structure of claim 1, wherein the particles are hollow and scatter light at the second wavelength.

5. The wavelength converting structure of claim 1, wherein the refractive index of the binder at the second wavelength is greater than or equal to about 1.65.

6. The wavelength converting structure of claim 1, wherein the coating comprises a layer of material having an index of refraction at the second wavelength less than the index of refraction of the binder at the second wavelength, the layer of material disposed on the first layer opposite from the layer of wavelength converting material.

7. The wavelength converting structure of claim 6, wherein the layer of material disposed on the first layer has an optical thickness of about ¼ of the second wavelength.

8. The wavelength converting structure of claim 1, wherein the coating comprises strongly light scattering cavities located in spaces between adjacent particles.

9. A light emitting device comprising:
a light emitting semiconductor diode structure; and
a coating disposed on a light output surface of the semiconductor diode structure, the coating comprising at least a first layer comprising particles dispersed in a binder, the first layer disposed on the light output surface, the binder having an index of refraction at the second wavelength greater than or equal to about 1.65.

10. The light emitting device of claim 9, wherein the particles are solid, transparent to light at the second wavelength, and have a refractive index at the second wavelength that matches or approximately matches the refractive index of the binder at the second wavelength.

11. The light emitting device of claim 9, wherein the particles are hollow and scatter light at the second wavelength.

12. The light emitting device of claim 9, wherein the coating comprises a layer of material having an index of refraction at the second wavelength less than the index of refraction of the binder at the second wavelength, the layer of material disposed on the first layer opposite from the layer of wavelength converting material.

13. The light emitting device of claim 12, wherein the layer of material disposed on the first layer has an optical thickness of about ¼ of the second wavelength.

14. The wavelength converting structure of claim 9, wherein the coating comprises strongly light scattering cavities located in spaces between adjacent particles.

15. A light emitting device comprising:
a light emitting semiconductor diode structure;
a wavelength converting structure disposed on the light emitting semiconductor diode structure, and
a coating disposed on a light output surface of the layer of wavelength converting material, the coating comprising at least a first layer comprising particles dispersed in a binder, the first layer disposed on the light output surface, the binder having an index of refraction at the second wavelength greater than or equal to an index of refraction at the second wavelength of the light output surface.

16. The light emitting device of claim 15, wherein the layer of wavelength converting material is or comprises a ceramic phosphor platelet.

17. An illumination system comprising:
an array of light emitting devices, each of the light emitting devices as in claim 15; and
an optic or optical system arranged to collect and direct light emitted by the light emitting devices.

18. The illumination system of claim 17, wherein some or all of the light emitting devices are independently controllable.

19. A mobile device comprising:
a camera;
a flash illumination system comprising:
a monolithic array of light emitting devices, each of the light emitting devices as in claim 15, some or all of which are independently controllable;
an optic or optical system arranged to collect and direct light emitted by the light emitting devices; and
a controller configured to operate the light emitting devices to match a field of view of the flash illumination system to a field of view of the camera.

20. A display system comprising:
a display;
a monolithic array of light emitting devices, each of the light emitting devices as in claim 15, some or all of which are independently controllable; and
an optic or optical system arranged to couple light from the array of light emitting devices into the display.
